(19) United States
(12) Patent Application Publication
(10) Pub. No.: US 2021/0265439 A1
(43) Pub. Date: Aug. 26, 2021

(54) PIXEL COMPENSATION CIRCUIT AND MANUFACTURING METHOD THEREOF, OLED ARRAY SUBSTRATE AND MANUFACTURING METHOD THEREOF, AND DISPLAY DEVICE

(71) Applicant: BOE TECHNOLOGY GROUP CO., LTD., Beijing (CN)

(72) Inventors: Jintao PENG, Beijing (CN); Yanan NIU, Beijing (CN); Kuanjun PENG, Beijing (CN); Kai GUO, Beijing (CN); Bin QIN, Beijing (CN); Xiaolong LI, Beijing (CN); Wanpeng TENG, Beijing (CN)

(21) Appl. No.: 17/255,866

(22) PCT Filed: Apr. 10, 2020
(86) PCT No.: PCT/CN2020/084175

§ 371 Date: Dec. 23, 2020

(30) Foreign Application Priority Data
Apr. 11, 2019 (CN) 201910290901.1

(51) Int. Cl. H01L 27/32

(52) U.S. Cl. CPC H01L 27/3262; H01L 2227/323; H01L 27/3258

(57) ABSTRACT

The present disclosure provides a pixel compensation circuit and a manufacturing method thereof, an OLED array substrate and a manufacturing method thereof, and a display device. The pixel compensation circuit includes a first TFT and a second TFT on a substrate. The first TFT includes: a first electrode on the substrate, a first interlayer dielectric layer on a side of the first electrode away from the substrate and having an opening exposing at least a portion of the first electrode; a second electrode on a side of the first interlayer dielectric layer away from the first electrode; and an active layer extending from the second electrode to the first electrode. The second TFT includes: an active layer on the substrate; and a first electrode and a second electrode in a same layer and on a side of the active layer of the second TFT away from the substrate.

### CROSS REFERENCE TO RELATED APPLICATIONS

This is a National Phase Application filed under 35 U.S.C. 371 as a national stage of PCT/CN2020/084175, filed on Apr. 10, 2020, an application claiming priority from Chinese patent application No. 201910290901.1, filed on Apr. 11, 2019 to the National Intellectual Property Administration, PRC, the contents of which are incorporated herein by reference in their entirety.

### TECHNICAL FIELD

The present disclosure relates to the field of display technologies, and in particular, to a pixel compensation circuit and a manufacturing method thereof, an organic light emitting diode array substrate and a manufacturing method thereof, and a display device.

### BACKGROUND

An organic light emitting diode (OLED) display device has advantages of high contrast, ultra-light weight, flexibility and the like. The OLED display device also provides a more vivid color and a larger color gamut than a conventional liquid crystal display device. In addition, the OLED display device can be manufactured to be more flexible, thinner, and lighter than the conventional liquid crystal display device.

### SUMMARY

An aspect of the present disclosure provides a pixel compensation circuit including a first thin film transistor (TFT) and a second TFT on a substrate. The first TFT includes: a first electrode on the substrate; a first interlayer dielectric layer on a side of the first electrode away from the substrate, the first interlayer dielectric layer having an opening exposing at least a portion of the first electrode; a second electrode on a side of the first interlayer dielectric layer away from the first electrode and outside the opening; and an active layer on a side of the second electrode and the first interlayer dielectric layer away from the substrate, the active layer extending from the second electrode to the first electrode through a sidewall of the opening of the first interlayer dielectric layer. The second TFT includes: an active layer on the substrate; and a first electrode and a second electrode in a same layer and on a side of the active layer of the second TFT away from the substrate. The first and second electrodes of the first TFT are a source electrode and a drain electrode, respectively, and the first and second electrodes of the second TFT are a source electrode and a drain electrode, respectively.

According to an embodiment of the present disclosure, the pixel compensation circuit incudes a plurality of first TFTs and one second TFT, channel lengths of the plurality of first TFTs are the same as each other, a channel length of the second TFT is different from the channel length of the first TFT, the plurality of first TFTs are switching transistors, and the second TFT is a driving transistor.

According to an embodiment of the present disclosure, the first TFT is an oxide TFT and the second TFT is a low temperature polysilicon TFT.

According to an embodiment of the present disclosure, the first electrode of the first TFT and a gate electrode of the second TFT are in a same layer and made of a same material.

According to an embodiment of the present disclosure, the first interlayer dielectric layer covers a gate electrode of the second TFT.

According to an embodiment of the present disclosure, the pixel compensation circuit further includes: a first gate insulating layer covering the second electrode of the first TFT, the active layer of the first TFT and the first interlayer dielectric layer, a gate electrode of the first TFT is on a side of the first gate insulating layer away from the active layer of the first TFT; and a second interlayer dielectric layer covering the gate electrode of the first TFT and the first gate insulating layer.

According to an embodiment of the present disclosure, the pixel compensation circuit further includes a second gate insulating layer covering the active layer of the second TFT and the substrate, the first electrode of the first TFT is on a side of the second gate insulating layer away from the substrate, and a gate electrode of the second TFT is on a side of the second gate insulating layer away from the active layer of the second TFT.

According to an embodiment of the present disclosure, the first and second electrodes of the second TFT are on a side of the second interlayer dielectric layer away from the first gate insulating layer and are connected to the active layer of the second TFT through via holes penetrating the second interlayer dielectric layer, the first gate insulating layer, the first interlayer dielectric layer, and the second gate insulating layer.

According to an embodiment of the present disclosure, an angle between the sidewall of the opening and an exposed portion of the first electrode of the first TFT is greater than 90 degrees.

Another aspect of the present disclosure provides an organic light emitting diode (OLED) array substrate including the pixel compensation circuit described above.

According to an embodiment of the present disclosure, the OLED array substrate further includes: a planarization layer covering the first and second electrodes of the second TFT; and an OLED having an anode on a side of the planarization layer away from the second TFT, the anode being connected to the first electrode of the second TFT through a via hole penetrating the planarization layer.

According to an embodiment of the present disclosure, the OLED array substrate further includes a buffer layer disposed between the substrate and the active layer of the second TFT.

Another aspect of the present disclosure provides a display device including the OLED array substrate described above.

According to an embodiment of the present disclosure, the display device is an active matrix OLED display device.

Another aspect of the present disclosure provides a method of manufacturing a pixel compensation circuit including forming a first TFT and a second TFT on a substrate. The first TFT includes: a first electrode on the substrate; a first interlayer dielectric layer on a side of the first electrode away from the substrate, the first interlayer dielectric layer having an opening exposing at least a portion of the first electrode; a second electrode on a side of the first interlayer dielectric layer away from the first electrode and outside the opening; and an active layer on a side of the second electrode and the first interlayer dielectric layer away from the substrate, the active layer extending from the second electrode to the first electrode through a sidewall of the opening of the first interlayer dielectric layer. The second TFT includes: an active layer on the substrate; and a first electrode and a second electrode in a same layer and on a side of the active layer of the second TFT away from the substrate.

According to an embodiment of the present disclosure, forming the first TFT and the second TFT on the substrate incudes: forming a buffer layer on the substrate, forming a low temperature polycrystalline silicon layer on a side of the buffer layer away from the substrate, and performing a first patterning process on the low temperature polycrystalline silicon layer to form the active layer of the second TFT; forming a first gate insulating layer on a side of the buffer layer away from the substrate and on a side of the second TFT away from the substrate; and forming a metal layer on a side of the first gate insulating layer away from the substrate, and performing a second patterning process on the metal layer to form the first electrode of the first TFT and a gate electrode of the second TFT.

According to an embodiment of the present disclosure, forming the first TFT and the second TFT on the substrate further includes: forming the first interlayer dielectric layer on a side of the first electrode of the first TFT away from the substrate and on a side of the gate electrode of the second TFT away from the substrate, and forming the opening in the first interlayer dielectric layer by a third patterning process, wherein the at least a portion of the first electrode of the first TFT is exposed by the opening; forming the second electrode of the first TFT on a side of the first interlayer dielectric layer away from the substrate, wherein the second electrode of the first TFT is outside the opening; forming an oxide layer on a side of the first and second electrodes of the first TFT away from the substrate and on the sidewall of the opening, and performing a fourth patterning process on the oxide layer to form the active layer of the first TFT, wherein the active layer of the first TFT is positioned on the a of the second electrode of the first TFT and the first interlayer dielectric layer away from the substrate and extends from the second electrode of the first TFT to the first electrode of the first TFT through the sidewall of the opening; forming a second gate insulating layer on a side of the second electrode and the active layer of the first TFT away from the substrate and on the side of the first interlayer dielectric layer away from the substrate; and forming a gate electrode of the first TFT on a side of the second gate insulating layer away from the substrate.

According to an embodiment of the present disclosure, forming the first TFT and the second TFT on the substrate further includes: forming a second interlayer dielectric layer on a side of the gate electrode of the first TFT away from the substrate and on the side of the second gate insulating layer away from the substrate; and forming the first and second electrodes of the second TFT on a side of the second interlayer dielectric layer away from the substrate, wherein the first and the second electrodes of the second TFT penetrate the second interlayer dielectric layer, the second gate insulating layer, the first interlayer dielectric layer and the first gate insulating layer and are connected to the active layer of the second TFT.

According to an embodiment of the present disclosure, forming the first TFT and the second TFT on the substrate includes forming a plurality of first TFTs having a same channel length and one second TFT having a channel length different from the channel length of the first TFTs.

Another aspect of the present disclosure provides a method of manufacturing a light emitting diode array substrate including: providing a substrate; forming a pixel compensation circuit on the substrate according to the method described above; forming a planarization layer on a side of the second interlayer dielectric layer of the pixel compensation circuit away from the substrate, so that the planarization layer covers the first and second electrodes of the second TFT; and forming an organic light emitting diode (OLED) on a side of the planarization layer away from the substrate, wherein an anode of the OLED is disposed on a side of the planarization layer away from the substrate and penetrates the planarization layer to connect to the first electrode of the second TFT.

### BRIEF DESCRIPTION OF THE DRAWINGS

The above and/or additional aspects and advantages of the present disclosure will become apparent and readily appreciated from following description of embodiments in conjunction with accompanying drawings, in which:

FIG. 1 shows a schematic diagram of a structure of a pixel compensation circuit according to an embodiment of the present disclosure;

FIG. 2 shows a schematic diagram of a structure of an OLED array substrate according to an embodiment of the present disclosure;

FIG. 3 shows a flow diagram of a method of manufacturing a pixel compensation circuit according to an embodiment of the present disclosure; and

FIG. 4 shows a flow chart of a method of manufacturing a pixel compensation circuit and a method of manufacturing an OLED array substrate according to an embodiment of the present disclosure.

### DETAILED DESCRIPTION

Reference will now be made in detail to embodiments of the present disclosure, examples of the embodiments are illustrated in accompanying drawings in which like reference numerals throughout refer to the same or similar elements or elements having the same or similar functions. The embodiments described below with reference to the accompanying drawings are illustrative only for a purpose of explaining the present disclosure, and are not to be construed as limiting the present disclosure.

An OLED display device generally has a problem of poor luminance uniformity. Currently, the problem is generally solved by using a compensation technique, which includes an internal compensation and an external compensation. The internal compensation refers to a method of performing compensation by using thin film transistors (TFTs) to construct a compensation circuit inside a pixel. For a purpose of achieving compensation, an internal pixel compensation circuit generally includes a plurality of TFTs and a plurality of capacitors. However, excessive number and size of the TFTs and the capacitors in the internal pixel compensation circuit directly affect resolution of the display device and limit increase of pixel density (PPI) of the display device. Therefore, a structure of the compensation circuit on an OLED array substrate still needs to be improved.

The present disclosure provides a pixel compensation circuit applied to an OLED array substrate.

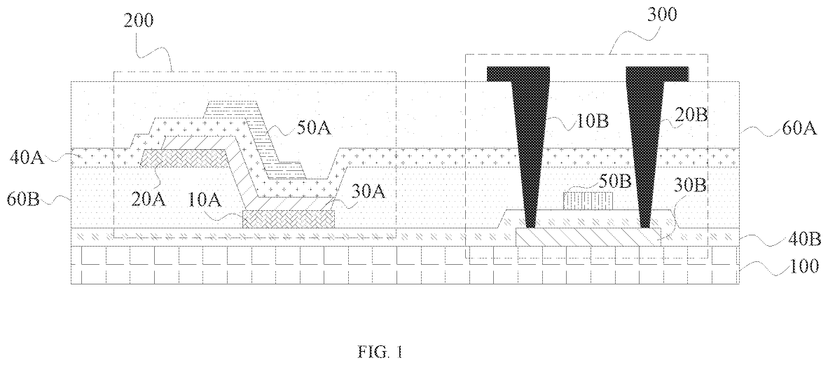

FIG. 1 shows a schematic diagram of a structure of a pixel compensation circuit according to an embodiment of the present disclosure. Referring to FIG. 1, the pixel compensation circuit includes a first TFT 200 and a second TFT 300 on a substrate 100.

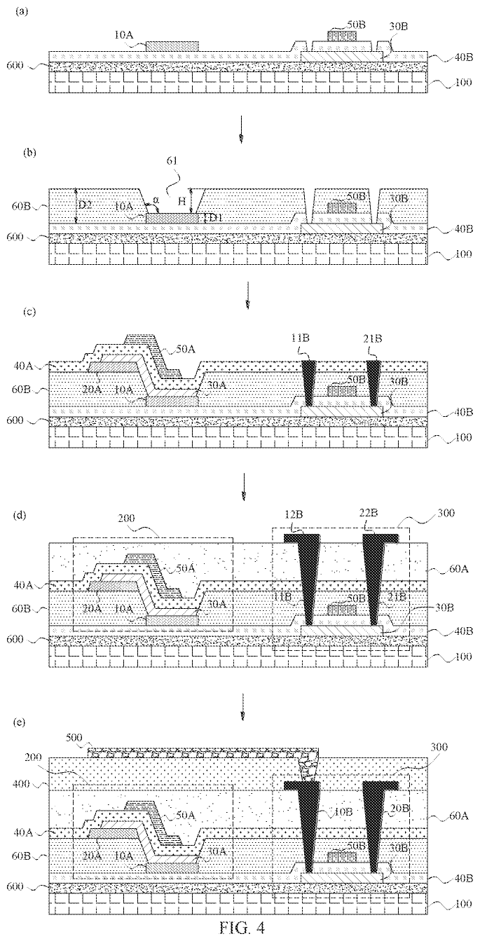

A first electrode 10A of the first TFT 200 is positioned on the substrate 100, a first interlayer dielectric layer 60B is disposed between the first electrode 10A and a second electrode 20A of the first TFT 200, the first interlayer dielectric layer 60B has an opening 61 (referring to (b) in FIG. 4) exposing at least a portion of the first electrode 10A of the first TFT 200, the second electrode 20A of the first TFT 200 is positioned outside the opening 61 of the first interlayer dielectric layer 60B, and an active layer 30A of the first TFT 200 is positioned on a side of the second electrode 20A and the first interlayer dielectric layer 60B of the first TFT 200 away from the substrate 100 and extends from the second electrode 20A of the first TFT 200 to the first electrode 10A of the first TFT 200 via the opening 61 of the first interlayer dielectric layer 60B.

An active layer 30B of the second TFT 300 is positioned on the substrate 100. A first electrode 10B and a second electrode 20B of the second TFT 300 are positioned in a same layer and positioned on a side of the active layer 30B of the second TFT 300 away from the substrate 100.

According to an embodiment of the present disclosure, the first electrode 10A and the second electrode 20A of the first TFT 200 are a source electrode and a drain electrode, respectively, and the first electrode 10B and the second electrode 20B of the second TFT 300 are a source electrode and a drain electrode, respectively.

According to an embodiment of the present disclosure, the pixel compensation circuit may include a plurality of first TFTs 200 and one second TFT 300, in which case a channel length of each first TFT 200 is the same and is different from a channel length of the second TFT 300.

According to an embodiment of the present disclosure, the first electrode 10A of the first TFT 200 is positioned on the substrate 100, the first interlayer dielectric layer 60B is disposed between the first electrode 10A and the second electrode 20A of the first TFT 200, the first interlayer dielectric layer 60B has the opening 61 exposing at least a portion of the first electrode 10A of the first TFT 200, and the active layer 30A of the first TFT 200 is positioned on the side of the first electrode 10A and the second electrode 20A of the first TFT 200 away from the substrate 100 and on a sidewall of the opening 61. Thus, the first TFT 200 has a vertical structure in which the first electrode 10A and the second electrode 20A are disposed in different layers. The active layer 30B of the second TFT 300 is positioned on the substrate 100, and the first electrode 10B and the second electrode 20B of the second TFT 300 are positioned in a same layer and positioned on the side of the active layer 30B of the second TFT 300 away from the substrate 100. Thus, the second TFT 300 has a planar structure in which the first electrode 10B and the second electrode 20B are disposed on the same layer.

It will be understood by those skilled in the art, since functions of a row driving circuit region (GOA region) are different from those of a display region, TFTs with different width-to-length ratios are generally required to be disposed in the pixel compensation circuit. According to an embodiment of the present disclosure, the first TFTs 200 having the same channel length in the pixel compensation circuit are disposed in the vertical structure, and the second TFT 300 having different channel length from that of the first TFTs 200 is disposed in the planar structure, so that the pixel compensation circuit may have the TFTs with the different width-to-length ratios. Moreover, a TFT having the vertical structure has a size smaller than a TFT having the planar structure, so that the pixel compensation circuit according to an embodiment of the present disclosure adopts a manner of combining the TFTs having the vertical structure and the TFT having the planar structure, and has a smaller size than a pixel compensation circuit composed of the TFTs having the planar structure only, thus resolution and pixel density of a display device adopting an OLED array substrate including the pixel compensation circuit can be improved effectively.

For ease of understanding, respective structures of the pixel compensation circuit according to an embodiment of the present disclosure are explained in detail below.

According to an embodiment of the present disclosure, the first TFT 200 may be an oxide TFT, and the second TFT 300 may be a low temperature polycrystalline silicon (LTPS) TFT. That is, the active layer 30A of the first TFT 200 is formed of an oxide material, and the active layer 30B of the second TFT 300 is formed of a low temperature polysilicon material. The oxide TFT has an advantage of low leakage current, and the LTPS TFT has advantages of high mobility and high on-state current. The display device adopting the OLED array substrate including the pixel compensation circuit has advantages of high reaction speed, low cost, low power consumption and the like by applying a low-temperature polycrystalline oxide (LTPO) technology to the pixel compensation circuit. According to an embodiment of the present disclosure, the oxide TFT may serve as a switching TFT in the pixel compensation circuit and the LTPS TFT may serve as a driving TFT in the pixel compensation circuit.

According to an embodiment of the present disclosure, referring to FIG. 1, the first electrode 10A of the first TFT 200 and a gate electrode 50B of the second TFT 300 are positioned on a same layer and made of a same material, and thus, in a manufacturing process, the first electrode 10A of the first TFT 200 and the gate electrode 50B of the second TFT 300 may be simultaneously formed by using a same patterning process, so that the manufacturing process is simplified.

According to an embodiment of the present disclosure, referring to FIG. 1, the first interlayer dielectric layer 60B covers the gate electrode 50B of the second TFT 300 and has the opening 61 at a position corresponding to the first electrode 10A of the first TFT 200 (as shown in (b) in FIG. 4). The opening 61 of the first interlayer dielectric layer 60B exposes an upper surface of the first electrode 10A of the first TFT 200 (as shown in (b) in FIG. 4), that is, a sum of a height H of the opening 61 and a thickness D1 of the first electrode 10A of the first TFT 200 matches a thickness D2 of the first interlayer dielectric layer 60B (as shown in (b) in FIG. 4). The second electrode 20A of the first TFT 200 is disposed on a side of the first interlayer dielectric layer 60B away from the first electrode 10A of the first TFT 200 and outside the opening 61. The active layer 30A of the first TFT 200 covers the second electrode 20A of the first TFT 200 and the sidewall of the opening 61 and extends onto an upper surface of the first electrode 10A of the first TFT 200, such that the active layer 30A of the first TFT 200 is connected with the first electrode 10A and the second electrode 20A of the first TFT 200.

A region of the active layer 30A of the first TFT 200 covering the sidewall of the opening 61 is a channel region of the first TFT 200. When the sidewall of the opening 61 of the first interlayer dielectric layer 60B is inclined to a certain degree, the channel length of the first TFT 200 is determined by the thickness of the first interlayer dielectric layer 60B, so that the channel length of the first TFT 200 is not limited by exposure processes during the manufacturing process, thereby simplifying the manufacturing process. An inclination degree of the sidewall of the opening 61 of the first interlayer dielectric layer 60B is not particularly limited as long as the inclination degree is advantageous to reduce a size of the first TFT 200 and ensure continuity of the active layer 30A of the first TFT 200, and the inclination degree may be designed by those skilled in the art according to specific situations. For example, according to an embodiment of the present disclosure, an angle between the sidewall of the opening 61 and an exposed portion of the first electrode 10A of the first TFT 200 is greater than 90 degrees (as shown by ‘α’ in (b) in FIG. 4). Thus, it can be ensured that the active layer 30A of the first TFT 200 is continuously disposed.

If all TFTs in the pixel compensation circuit are disposed in the vertical structure, in order to manufacture the TFTs having different width-to-length ratios, the first interlayer dielectric layer 60B with different thicknesses is required to be disposed, which will significantly increase process difficulty. Moreover, except a driving TFT, the switching TFTs in the pixel compensation circuit have a same channel length, so that the TFTs having different width-to-length ratios in the pixel compensation circuit can be realized by disposing the switching TFTs (i.e., the first TFTs) having the same channel length to be the vertical structure and disposing the driving TFT (i.e., the second TFT 300) having a channel length different from that of the switching TFTs to be the planar structure. Besides, the same channel length of all the first TFTs 200 can be implemented by disposing the first interlayer dielectric layer 60B having a certain thickness, and a surface of the first interlayer dielectric layer 60B is flat, reducing the process difficulty. The pixel compensation circuit adopting the manner of combining the TFTs having the vertical structure and the TFT having the planar structure can effectively reduce a size of the pixel compensation circuit, in a case where usage function of the pixel compensation circuit is not influenced, so that the resolution and the pixel density of the display device adopting the OLED array substrate including the pixel compensation circuit can be improved effectively.

The thickness of the first interlayer dielectric layer 60B is not particularly limited, and those skilled in the art may design it according to requirements of different products.

According to an embodiment of the present disclosure, referring to FIG. 1, the first TFT 200 includes the first electrode 10A, the first interlayer dielectric layer 60B, the second electrode 20A, the active layer 30A, a first gate insulating layer 40A, a gate electrode 50A, and a second interlayer dielectric layer 60A. The first electrode 10A is disposed close to the substrate 100, the first interlayer dielectric layer 60B has the opening 61 at a position corresponding to the first electrode 10A, the opening 61 of the first interlayer dielectric layer 60B exposes the upper surface of the first electrode 10A. The second electrode 20A is disposed at the side of the first interlayer dielectric layer 60B away from the first electrode 10A and is disposed close to the sidewall of the opening 61. The active layer 30A covers the second electrode 20A and the sidewall of the opening 61 and extends onto the upper surface of the first electrode 10A to be connected with the first electrode 10A and the second electrode 20A. The first gate insulating layer 40A covers the second electrode 20A, the active layer 30A and the first interlayer dielectric layer 60B. The gate electrode 50A is disposed on a side of the first gate insulating layer 40A away from the active layer 30A, and the second interlayer dielectric layer 60A covers the gate electrode 50A and the first gate insulating layer 40A. Therefore, the first TFT 200 has the vertical structure, and the size of the first TFT can be effectively reduced in the case where the usage function of the pixel compensation circuit is not influenced, thus the size of the pixel compensation circuit also can be reduced, so that the resolution and the pixel density of the display device adopting the OLED array substrate including the pixel compensation circuit are improved effectively. Besides, a current conduction direction of the TFTs having the vertical structure is perpendicular to the substrate, thus in a flexible product, electrical characteristics of the TFTs having the vertical structure are not influenced by a curvature radius.

According to an embodiment of the present disclosure, by designing the thickness of the first interlayer dielectric layer 60B, the first TFT 200 having the channel length less than 1 μm may be obtained.

According to an embodiment of the present disclosure, referring to FIG. 1, the second TFT 300 includes the active layer 30B, a second gate insulating layer 40B, the gate electrode 50B, the first interlayer dielectric layer 60B, the first gate insulating layer 40A, the second interlayer dielectric layer 60A, the first electrode 10B and the second electrode 20B. The active layer 30B is disposed on the substrate 100. The second gate insulating layer 40B covers the active layer 30B and the substrate 100. The gate electrode 50B is disposed on a side of the second gate insulating layer 40B away from the active layer 30B. The first interlayer dielectric layer 60B covers the gate electrode 50B. The first gate insulating layer 40A and the second interlayer dielectric layer 60A are disposed sequentially on a side of the first interlayer dielectric layer 60B away from the gate electrode 50B. The first electrode 10B and the second electrode 20B are disposed on a side of the second interlayer dielectric layer 60A away from the first gate insulating layer 40A, and connected with the active layer 30B through via holes penetrating the second interlayer dielectric layer 60A, the first gate insulating layer 40A, the first interlayer dielectric layer 60B, and the second gate insulating layer 40B. Therefore, the TFTs having different width-to-length ratios can be obtained by disposing the driving TFT in the pixel compensation circuit to be the plane structure to realize compensation function of the pixel compensation circuit.

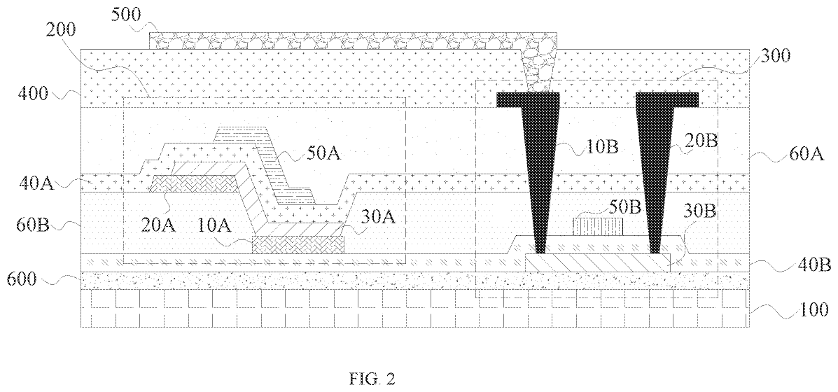

FIG. 2 shows a schematic diagram of a structure of an OLED array substrate according to an embodiment of the present disclosure.

Referring to FIG. 2, the OLED array substrate according to an embodiment of the present disclosure may further include a planarization layer 400 and an OLED. The planarization layer 400 is positioned on a side of the second interlayer dielectric layer 60A away from the substrate 100 and covers the first electrode 10B and the second electrode 20B of the second TFT 300. An anode 500 of the OLED is disposed on a side of the planarization layer 400 away from the second TFT 300 and connected to the first electrode 10B of the second TFT 300 through a via hold penetrating the planarization layer 400. Therefore, brightness compensation of pixel units in the OLED can be realized by using the pixel compensation circuit shown in FIG. 1, and the pixel compensation circuit has a smaller size, so that, in a case where compensation function of the pixel compensation circuit is ensured, the resolution and the pixel density of the display device adopting the OLED array substrate can be effectively improved.

According to an embodiment of the present disclosure, the OLED array substrate may further include a buffer layer 600 disposed between the active layer 30B of the second TFT 300 and the substrate 100, so that adhesion between the active layer 30B of the second TFT 300 and the substrate 100 can be enhanced, and performance of the device can be improved.

The present disclosure also provides a display device. According to an embodiment of the present disclosure, the display device includes a housing and the OLED array substrate described above. The housing includes a front frame and a back plate which form an accommodating space in which the OLED array substrate is positioned, and a light exiting side of the OLED array substrate is disposed away from the back plate. Therefore, the display device has all features and advantages of the OLED array substrate described above, and will not be described herein again. Generally, the display device has higher resolution and higher pixel density.

According to an embodiment of the present disclosure, the display device may be an active matrix OLED array substrate display device.

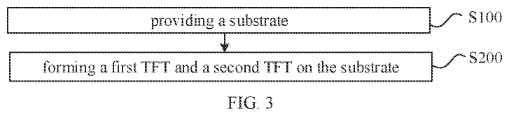

FIG. 3 shows a flowchart of a method of manufacturing a pixel compensation circuit according to an embodiment of the present disclosure, and FIG. 4 shows schematic diagrams of a flowchart of a method of manufacturing a pixel compensation circuit and a method of manufacturing an OLED array substrate including the pixel compensation circuit according to an embodiment of the present disclosure.

According to an embodiment of the present disclosure, referring to FIG. 3, the method of manufacturing the pixel compensation circuit includes step S100 and S200.

In step S100, a substrate is provided.

According to an embodiment of the present disclosure, a material of the substrate is not particularly limited, and those skilled in the art may design the substrate according to specific situations. For example, according to an embodiment of the present disclosure, the substrate may be a rigid substrate or a flexible substrate. According to an embodiment of the present disclosure, a compensation circuit region is defined on the substrate, so that a compensation circuit may be disposed in the area with subsequent steps to achieve compensation of brightness of pixel units in a final product.

In step S200, a first TFT and a second TFT are formed on the substrate.

According to an embodiment of the present disclosure, before disposing the TFTs on the substrate, a buffer layer may be formed on the substrate in advance, and the first TFT and the second TFT may be formed on the buffer layer. Therefore, adhesion between the TFTs disposed subsequently and the substrate can be enhanced.

According to an embodiment of the present disclosure, the first TFT is formed to include: a first electrode positioned on the substrate; a first interlayer dielectric layer including an opening which exposes at least a portion of the first electrode and positioned on a side of the first electrode of the first TFT away from the substrate; a second electrode positioned on a side of the first interlayer dielectric layer away from the first electrode of the first TFT and outside the opening; and an active layer positioned on a side of the second electrode and the first interlayer dielectric layer of the first TFT away from the substrate and extending from the second electrode of the first TFT to the first electrode of the first TFT through a sidewall of the opening of the first interlayer dielectric layer.

According to an embodiment of the present disclosure, the second TFT is formed to include: an active layer positioned on the substrate: a first electrode and a second electrode which are positioned on a same layer and on a side of the active layer of the second TFT away from the substrate.

According to an embodiment of the present disclosure, a plurality of first TFTs and one second TFT may be formed on the substrate. A channel length of each first TFT is the same and is different from that of the second TFT.

Therefore, the first TFT has a vertical structure, the second TFT has a planar structure, a size of the pixel compensation circuit can be effectively reduced, and resolution and pixel density of a display device adopting an OLED array substrate including the pixel compensation circuit can be improved.

A principle of disposing the first TFT to be the vertical structure and disposing the second TFT to be the planar structure has been described in detail above, and will not be described herein again. A process of manufacturing the pixel compensation circuit and a process of manufacturing the OLED array substrate including the pixel compensation circuit will be described in detail with reference to FIG. 4.

According to an embodiment of the present disclosure, referring to (a) in FIG. 4, first, a low temperature polysilicon layer is formed on a side of a buffer layer 600 away from the substrate 100, and the low temperature polysilicon layer is processed by using a patterning process to form an active layer 30B of a second TFT 300. Subsequently, a second gate insulating layer 40B is formed on a side of the buffer layer 600 away from the substrate 100 and on a side of the active layer 30B of the second TFT 300 away from the substrate 100, and two via holes are formed in the second gate insulating layer 40B by using a patterning process. Next, a metal layer is formed on a side of the second gate insulating layer 40B away from the buffer layer 600, and a first electrode 10A of a first TFT 200 and a gate electrode 50B of the second TFT 300 are synchronously formed by processing the metal layer with a patterning process.

Referring to (b) in FIG. 4, subsequently, a first interlayer dielectric layer 60B is formed on a side of the first electrode 10A of the first TFT 200 away from the second gate insulating layer 40B and a side of the gate electrode 50B of the second TFT 300 away from the second gate insulating layer 40B, and an opening 61 is formed in the first interlayer dielectric layer 60B by using a patterning process. The first interlayer dielectric layer 60B is broken at the opening 61 and exposes at least a portion of the first electrode 10A of the first TFT 200, and via holes are formed in regions of the first interlayer dielectric layer 60B corresponding to the via holes in the second gate insulating layer 40B.

It should be noted that, in the process of forming the opening 61 in the first interlayer dielectric layer 60B, inclination degree of a sidewall of the opening 61 needs to be modified to avoid fracture of an active layer of the first TFT 200 to be subsequently disposed due to the inclination degree is too steep. Those skilled in the art may design the specific inclination degree according to specific situations as long as the inclination degree is beneficial to reduce a size of the first TFT 200 and ensure continuity of the active layer of the first TFT 200.

According to an embodiment of the present disclosure, an angle between the sidewall of the opening 61 and an exposed portion of the first electrode 10A of the first TFT 200 is greater than 90 degrees.

Referring to (c) in FIG. 4, subsequently, a second electrode 20A of the first TFT 200 is formed on a side of the first interlayer dielectric layer 60B away from the first electrode 10A of the first TFT 200, and the second electrode 20A of the first TFT 200 is close to and outside of the opening 61. Next, an oxide layer is formed on a side of the second electrode 20A and the first electrode 10A of the first TFT 200 away from the second gate insulating layer 40B, and an active layer 30A of the first TFT 200 is formed by performing a patterning process on the oxide layer. The active layer 30A of the first TFT 200 covers the second electrode 20A of the first TFT 200, the sidewall of the opening 61 in the first interlayer dielectric layer 60B, and an exposed surface of the first electrode 10A of the first TFT 200 to connected to the first electrode 10A and the second electrode 20A of the first TFT 200. Next, a first gate insulating layer 40A is formed on a side of the second electrode 20A and the active layer 30A of the first TFT 200 away from the second gate insulating layer 40B and on a side of the first interlayer dielectric layer 60B away from the second gate insulating layer 40B, and via holes are formed in regions in the first gate insulating layer 40A corresponding to the via holes in the first interlayer dielectric layer 60B by using a patterning process. Next, a gate electrode 50A of the first TFT 200 is formed on a side of the first gate insulating layer 40A away from the first interlayer dielectric layer 60B, and a first electrode lower portion 11B and a second electrode lower portion 21B of the second TFT 300 are formed in via holes penetrating the first gate insulating layer 40A, the first interlayer dielectric layer 60B, and the second gate insulating layer 40B.

Referring to (d) in FIG. 4, subsequently, a second interlayer dielectric layer 60A is formed on a side of the gate electrode 50A of the first TFT 200 and the first gate insulating layer 40A away from the first interlayer dielectric layer 60B, and via holes are formed in regions in the second interlayer dielectric layer 60A corresponding to the via holes in the first gate insulating layer 40A by using a patterning process. Next, a first electrode upper portion 12B and a second electrode upper portion 22B of the second TFT 300 are formed on a side of the second interlayer dielectric layer 60A away from the gate electrode 50A, and the first electrode upper portion 12B and the second electrode upper portion 22B are connected to the first electrode lower portion 11B and the second electrode lower portion 21B through via holes penetrating the second interlayer dielectric layer 60A, respectively, to form a first electrode 10B and a second electrode 20B of the second TFT 300, thereby completing manufacturing of the pixel compensation circuit.

According to an embodiment of the present disclosure, the first TFT 200 is an oxide TFT and may be used as a switching TFT in the pixel compensation circuit, and the second TFT 300 is a low temperature polysilicon TFT and may be used as a driving TFT in the pixel compensation circuit. Therefore, a low temperature polycrystalline oxide technology is applied to the pixel compensation circuit, so that power consumption of a product including the pixel compensation circuit can be reduced, and reaction speed of the product can be improved.

According to an embodiment of the present disclosure, although (a), (b), (c) in FIG. 4 respectively show that the via holes for forming the first electrode 10B and the second electrode 20B of the second TFT 300 are respectively formed in steps of forming of the second gate insulating layer 40B, forming of the first interlayer dielectric layer 60B, and forming of the first gate insulating layer 40A, the first electrode lower portion 11B and the second electrode lower portion 21B of the second TFT 300 are first formed in the via holes penetrating the second gate insulating layer 40B, the first interlayer dielectric layer 60B, and the first gate insulating layer 40A after forming of the first gate insulating layer 40A, and the first electrode upper portion 12B and the second electrode upper portion 22B of the second TFT 300 are formed in the via holes penetrating the second interlayer dielectric layer 60A after forming of the second interlayer dielectric layer 60A and forming of the via holes penetrating the second interlayer dielectric layer 60A described with reference to (d) in FIG. 4, thereby forming the first electrode 10B and the second electrode 20B of the second TFT 300, the present disclosure is not limited thereto, for example, after the second gate insulating layer 40B, the first interlayer dielectric layer 60B, and the first gate insulating layer 40A are respectively formed, via holes may not be formed, but after the second interlayer dielectric layer 60A is subsequently formed, via holes penetrating the second gate insulating layer 40B, the first interlayer dielectric layer 60B, the first gate insulating layer 40A, and the second interlayer dielectric layer 60A may be formed at once through a patterning process, and the first electrode 10B and the second electrode 20B of the second TFT 300 may be formed in the formed via holes.

According to an embodiment of the present disclosure, a plurality of first TFTs 200 and one second TFT 300 may be formed according to the above-described method, and the channel length of each first TFT 200 is the same and is different from the channel length of the second TFT 300.

According to an embodiment of the present disclosure, the switching TFTs (i.e., the first TFTs 200) having the same channel length is disposed to be the vertical structure, the driving TFT (i.e., the second TFT 300) having the channel length different from that of the switching TFTs is disposed to be the planar structure, the TFTs with different width-to-length ratios in the pixel compensation circuit can be achieved. Besides, the same channel length of all the first TFTs 200 can be implemented by disposing the first interlayer dielectric layer 60B having a certain thickness, so that process difficulty is reduced, and a size of the pixel compensation circuit can be effectively reduced by combining the TFTs having the vertical structure and the TFT having the planar structure, thereby effectively improving resolution and pixel density of a display device adopting an OLED array substrate including the pixel compensation circuit.

According to an embodiment of the present disclosure, a method of manufacturing an OLED array substrate including the pixel compensation circuit includes steps described with reference to (e) in FIG. 4 in addition to the steps described with reference to (a), (b), (c), and (d) in FIG. 4, that is, a planarization layer 400 is formed on a side of the second interlayer dielectric layer 60A away from the gate electrode 50A of the first TFT 200, the planarization layer 400 covers the first electrode 10B and the second electrode 20B of the second TFT 300, and a via hole is formed in the planarization layer 400 by using a patterning process. Subsequently, an anode electrode 50 of an OLED is formed on a side of the planarization layer 400 away from the second TFT 300, and the anode electrode 500 is connected to the first electrode 10B of the second TFT through a via hole penetrating the planarization layer 400. Therefore, brightness of pixel units in the OLED array substrate can be compensated by using the pixel compensation circuit composed of the TFTs having the vertical structure and the TFT having the planar structure, the size of the pixel compensation circuit can be effectively reduced in a case where usage function of the pixel compensation circuit is not influenced, and the resolution and the pixel density of the display device adopting the OLED array substrate including the pixel compensation circuit are improved.

In the description of the present disclosure, orientations or positional relationships indicated by terms “upper”, “lower”, and the like are orientations or positional relationships as shown in the accompanying drawings, which are merely for convenience of describing the present disclosure and do not require that the present disclosure must be constructed and operated in a specific orientation, and thus, should not be construed as limiting the present disclosure.

Reference throughout the specification to the description of “an embodiment,” “another embodiment,” or the like, means that a particular feature, structure, material, or characteristic described in connection with the embodiment is included in at least one embodiment of the present disclosure. In the specification, schematic representations of the terms used above are not necessarily intended to refer to the same embodiment or example. Furthermore, the particular features, structures, materials, or characteristics described may be combined in any suitable manner in any one or more embodiments or examples. Moreover, various embodiments or examples and features of various embodiments or examples described in the specification can be combined and grouped by those skilled in the art without being mutually inconsistent. In addition, it should be noted that terms “first” and “second” in the specification are used for descriptive purposes only and are not to be construed as indicating or implying relative importance or implicitly indicating amounts of indicated technical features.

Dimensions of various elements in the accompanying drawings of the present disclosure are for illustrative purposes only and are not intended to limit the dimensions of the various elements as shown in the accompanying drawings.

While embodiments of the present disclosure have been shown and described above, it will be understood that the above embodiments are exemplary and not to be construed as limiting the present disclosure, and changes, modifications, substitutions and alterations may be made to the above embodiments by those ordinary skill in the art within the scope of the present disclosure.

1. A pixel compensation circuit, comprising: a first thin film transistor (TFT) and a second TFT on a substrate, wherein
the first TFT comprises:
a first electrode on the substrate;
a first interlayer dielectric layer on a side of the first electrode away from the substrate, the first interlayer dielectric layer having an opening exposing at least a portion of the first electrode;
a second electrode on a side of the first interlayer dielectric layer away from the first electrode, the second electrode being outside the opening; and
an active layer on a side of the second electrode and the first interlayer dielectric layer away from the substrate, the active layer extending from the second electrode to the first electrode through a sidewall of the opening of the first interlayer dielectric layer,
the second TFT comprises:
an active layer on the substrate; and
a first electrode and a second electrode in a same layer and on a side of the active layer of the second TFT away from the substrate,
wherein the first and second electrodes of the first TFT are a source electrode and a drain electrode, respectively, and the first and second electrodes of the second TFT are a source electrode and a drain electrode, respectively.

2. The pixel compensation circuit of claim 1, comprising a plurality of first TFTs and one second TFT, wherein channel lengths of the plurality of first TFTs are the same as each other, a channel length of the second TFT is different from the channel length of the first TFT, the plurality of first TFTs are switching transistors, and the second TFT is a driving transistor.

3. The pixel compensation circuit of claim 1, wherein the first TFT is an oxide TFT and the second TFT is a low temperature polysilicon TFT.

4. The pixel compensation circuit of claim 1, wherein the first electrode of the first TFT and a gate electrode of the second TFT are in a same layer and made of a same material.

5. The pixel compensation circuit of claim 1, wherein the first interlayer dielectric layer covers a gate electrode of the second TFT.

6. The pixel compensation circuit of claim 1, further comprising:
a first gate insulating layer covering the second electrode of the first TFT, the active layer of the first TFT and the first interlayer dielectric layer, wherein a gate electrode of the first TFT is on a side of the first gate insulating layer away from the active layer of the first TFT; and
a second interlayer dielectric layer covering the gate electrode of the first TFT and the first gate insulating layer.

7. The pixel compensation circuit of claim 6, further comprising:
a second gate insulating layer covering the active layer of the second TFT and the substrate, wherein the first electrode of the first TFT is on a side of the second gate insulating layer away from the substrate, and a gate electrode of the second TFT is on a side of the second gate insulating layer away from the active layer of the second TFT.

8. The pixel compensation circuit of claim 7, wherein the first and second electrodes of the second TFT are on a side of the second interlayer dielectric layer away from the first gate insulating layer and are connected to the active layer of the second TFT through via holes penetrating the second interlayer dielectric layer, the first gate insulating layer, the first interlayer dielectric layer, and the second gate insulating layer.

9. The pixel compensation circuit of claim 1, wherein an angle between the sidewall of the opening and an exposed portion of the first electrode of the first TFT is greater than 90 degrees.

10. An organic light emitting diode (OLED) array substrate, comprising the pixel compensation circuit of claim 1.

11. The OLED array substrate of claim 10, further comprising:
a planarization layer covering the first and second electrodes of the second TFT; and
an OLED having an anode on a side of the planarization layer away from the second TFT, the anode being connected to the first electrode of the second TFT through a via hole penetrating the planarization layer.

12. The OLED array substrate of claim 11, further comprising:
a buffer layer between the substrate and the active layer of the second TFT.

13. A display device, comprising the OLED array substrate of claim 10.

14. The display device of claim 13, wherein the display device is an active matrix OLED display device.

15. A method of manufacturing a pixel compensation circuit, comprising:
forming a first thin film transistor (TFT) and a second TFT on a substrate, wherein
the first TFT comprises:
a first electrode on the substrate;
a first interlayer dielectric layer on a side of the first electrode away from the substrate, the first interlayer dielectric layer having an opening exposing at least a portion of the first electrode;
a second electrode on a side of the first interlayer dielectric layer away from the first electrode, the second electrode being outside the opening; and
an active layer on a side of the second electrode and the first interlayer dielectric layer away from the substrate, the active layer extending from the second electrode to the first electrode through a sidewall of the opening of the first interlayer dielectric layer,
the second TFT comprises:
an active layer on the substrate; and
a first electrode and a second electrode in a same layer and on a side of the active layer of the second TFT away from the substrate.

16. The method of claim 15, wherein forming the first TFT and the second TFT on the substrate comprises:
forming a buffer layer on the substrate, forming a low temperature polycrystalline silicon layer on a side of the buffer layer away from the substrate, and performing a first patterning process on the low temperature polycrystalline silicon layer to form the active layer of the second TFT;
forming a first gate insulating layer on a side of the buffer layer away from the substrate and on a side of the second TFT away from the substrate; and
forming a metal layer on a side of the first gate insulating layer away from the substrate, and performing a second patterning process on the metal layer to form the first electrode of the first TFT and a gate electrode of the second TFT.

17. The method of claim 16, wherein forming the first TFT and the second TFT on the substrate further comprises:
forming the first interlayer dielectric layer on a side of the first electrode of the first TFT away from the substrate and on a side of the gate electrode of the second TFT away from the substrate, and forming the opening in the first interlayer dielectric layer by a third patterning process, wherein the at least a portion of the first electrode of the first TFT is exposed by the opening;
forming the second electrode of the first TFT on a side of the first interlayer dielectric layer away from the substrate, wherein the second electrode of the first TFT is outside the opening;
forming an oxide layer on a side of the first and second electrodes of the first TFT away from the substrate and on the sidewall of the opening, and performing a fourth patterning process on the oxide layer to form the active layer of the first TFT, wherein the active layer of the first TFT is positioned on a side of the second electrode of the first TFT and the first interlayer dielectric layer away from the substrate and extends from the second electrode of the first TFT to the first electrode of the first TFT through the sidewall of the opening;
forming a second gate insulating layer on a side of the second electrode and the active layer of the first TFT away from the substrate and on the side of the first interlayer dielectric layer away from the substrate; and
forming a gate electrode of the first TFT on a side of the second gate insulating layer away from the substrate.

18. The method of claim 17, wherein forming the first TFT and the second TFT on the substrate further comprises:
forming a second interlayer dielectric layer on a side of the gate electrode of the first TFT away from the substrate and on the side of the second gate insulating layer away from the substrate; and
forming the first and second electrodes of the second TFT on a side of the second interlayer dielectric layer away from the substrate, wherein the first and second electrodes of the second TFT penetrate the second interlayer dielectric layer, the second gate insulating layer, the first interlayer dielectric layer and the first gate insulating layer and are connected to the active layer of the second TFT.

19. The method of claim 15, wherein forming the first TFT and the second TFT on the substrate comprises:
forming a plurality of first TFTs having a same channel length and one second TFT having a channel length different from the channel length of the first TFTs.

20. A method of manufacturing a light emitting diode array substrate, comprising:
providing a substrate;
forming a pixel compensation circuit on the substrate according to the method of claim 15;
forming a planarization layer on a side of the second interlayer dielectric layer of the pixel compensation circuit away from the substrate, so that the planarization layer covers the first and second electrodes of the second TFT; and
forming an organic light emitting diode (OLED) on a side of the planarization layer away from the substrate, wherein an anode of the OLED is disposed on a side of the planarization layer away from the substrate and penetrates the planarization layer to connect to the first electrode of the second TFT.
